(19) United States
(12) Patent Application Publication
(10) Pub. No.: US 2012/0298167 A1
(43) Pub. Date: Nov. 29, 2012

(54) Structure and manufacturing of solar panels for a kind of solar shingles

(76) Inventors: Song Ping Zhou, Burlington (CA); Lihui Guo, Burlington (CA)

(21) Appl. No.: 13/149,452

(22) Filed: May 31, 2011

(30) Foreign Application Priority Data
May 24, 2011 (CA) 2,741,508

(51) Int. Cl. H01L 31/05; H01L 31/18

(52) U.S. Cl. 136/244; 438/66; 257/E31.113

(57) ABSTRACT

It is an invention of the structure and manufacturing process of a kind of solar panel, which particularly is for a kind of solar shingle. Junction box is designed at the central area of the solar panel. The bus-bars connecting the electrodes of the solar cell array and the junction box are laid to go over the backside of solar cell array. In order to avoid shorting the circuitry by bus-bars located between solar cells and to prevent delaminating of the layers of the solar cells around the area covered by the bus-bars, an isolating component is in interposed contact between the bus-bar and the solar cells.

### 1. TECHNICAL FIELD

The present invention relates to the use of solar power components (solar cells) to form solar panels which are applied on a building integrated photovoltaic system (BIPV).

### 2. BACKGROUND

Solar panels, in which crystalline silicon solar cells are laminated and electrically connected in series, are widely applied as a solar energy convertor in solar power generation systems.

Conventional crystalline silicon solar panels, shown schematically from view of front and rear sides in FIG. 1A and FIG. 1B, respectively and marked “Prior Art”, consist of a number of crystalline silicon solar cells electrically connected in series with soldering technology to form a solar cell array. Normally the number of cells can be more than a dozen or tens. Two bus-bars are welded at the two ends of the solar cell array (or series) in order to collect electric current generated by solar cells and lead it to a junction box. A conventional solar panel is shown in FIG. 1A and FIG. 1B. Reference 110 is the solar cell array made from solar cells. 111 is the front face of the solar cell array 110 to collect sunlight. 112 is the rear face of the solar cell array 110. Structure 130 is soldering tape to electrically connect the solar cells in series to form the solar cell array 110. 120 and 121 are soldering tapes for bus-bars connecting at the two ends of the solar cell array 110. 122 is a soldering tape to connect the two strips of solar cells in series. 150 is the back sheet of solar panel; 160 is the adhesive layer between the back sheet 150 and the solar cell array 110. 161 is the adhesive layer between the solar cell array 110 and the glass 170; 140 is the junction box, located at the edge of solar cell array 110; 141 and 142 are the cables coming out from the junction box 140 to electrically connect outside.

The junction box is normally located near an edge at the back side of the solar cell array, and very close to two ends of the solar cell array in order to let the bus-bars reach the junction box without crossing over any solar cell.

Two cables leading out from the junction box, with a connector at the end of each cable, enable the solar panel to connect with outside circuits.

Such conventional solar panels can be installed on a pitched roof above the roofing shingles to generate solar power. Because they are mounted top-up on the roofing shingles, the external appearance of building is damaged. Furthermore, there may be an economic loss when it becomes necessary to re-roof the building since the solar panels top-up on the roofing shingles have to be removed in order to replace worn roofing shingles during and then re-installed in a re-roofing process. The life-time of solar panels is longer than that of conventional roofing shingles.

United States patent application No. US2008/0190047 A1 (Allen) discloses a kind of solar shingle which comprises a metal shingle integrated with a solar panel. Combining with balance components disclosed in that invention patent, solar shingles can be mounted on a pitch rooftop like traditional roof shingles with a special function of generating electrical power and matching with the external appearance of buildings. And, the life-time of solar shingles is as long as that of solar panels. LUMAresources web site (www.lumaresources.com/datasheets.html), a kind of improved solar shingle was disclosed based on the patent application US2008/0190047 A1, the view of front and rear sides from which is schematically presented in FIG. 2A and FIG. 2B, marked “Prior Art”. 210 is the solar cell array made from solar cells; 211 is the front face of the solar cell array 210 to collect sunlight; 212 is the rear face of the solar cell array 210; 230 is soldering tape to electrically connect the solar cells in series to form the solar cell array 210; 220 and 221 are soldering tapes for bus-bars connecting at the two ends of the solar cell array 210; 222 is a soldering tape to connect the two strips of solar cells in series; 260 is the adhesive layer between the back sheet 250 and the solar cell array 210; 261 is the adhesive layer between the solar cell array 210 and the glass 270; 240 is the junction box, which locals at the central area of solar cell array 210; 241 and 242 are the cables coming out from the junction box 240 to electrically connect outside.

Comparing with the patent application US2008/0190047 A1, there are two differences. First, crystalline silicon solar panel is adopted to replace amorphous silicon thin film panel, which increases the output power and lifetime of solar shingle. Furthermore, crystalline silicon solar panel is the fastest cost reducing solar panel, which enhances the cost competitiveness of solar shingle. Secondly, the junction box is designed in the central area of solar cell array of a solar panel, so that the cables' connection with two neighboring solar shingles on a building roof can be realized at each lateral side of the solar shingle with a reasonable length of the cables. To connect solar shingles to each other at the lateral side of the solar shingle, instead of the underneath of it, is essential to install the solar shingle array on a building roof.

One of the ways to realize the connection is to lay the bus-bars along the outside of solar cell array, then connect them to the junction box. This can be done by using the technology and process the same as that used in the manufacturing of conventional solar panels. However, the disadvantage is that there will be a higher power loss in the array because of the need to use longer bus-bars, and bus-bars have an intrinsic electrical resistance. The width of solar panel has to be increased for the bus-bars to be laid along the outside of solar cell array. Those two cons will reduce the conversion efficiency of the solar panel, and then the solar shingle.

It is an object of the present invention to improve the technology and process to lead the two ends of the solar cell array to the junction box.

It is a further object of the invention to lay the bus-bars to go over the backside of solar cell array to get the shortest route between the ends of solar cell array and the junction box.

It is a further object of the present invention to avoid reliability problems conventionally related to the laying bus-bars over the backside of solar cell. Specifically, it is an object to avoid shorting the circuitry by bus-bars located between solar cells. It is yet another object to prevent delaminating of the layers of the solar cells around the area covered by the bus-bars.

### 1. SUMMARY OF THE INVENTION

To prevent and solve the above potential issues, the invention proposes an isolating component which is inserted between the bus-bars and the solar cell array. The function of this isolating component is to insulate the bus-bars and solar cell array, and to enhance the bonding strength between the layers in the area surrounding the bus-bars.

In a first embodiment, the invention is a solar plane comprising a plurality of crystalline silicon solar cells each having a front surface and a rear surface. The solar cells are electrically connected in solar arrays. A bus-bar is positioned adjacent the rear surfaces of the solar cells for electrical connection of the solar arrays to a junction box. An isolating component is in interposed contact between the bus-bar and the solar cells.

In a solar plane comprising a plurality of crystalline silicon solar cells each having a front surface and a rear surface, said solar cells being electrically connected in solar arrays and a bus-bar positioned adjacent the rear surfaces of the solar cells for electrical connection of the solar arrays to a junction box. A method is provided for avoiding shorting the circuitry of solar cells and solar areas by bus-bars located between solar cells comprising the step of: providing an isolating component in interposed contact between the bus-bar and the solar cells.

In accordance with the present invention a method of constructing a solar panel comprises the following steps. A glass substrate is provided and a first adhesive layer is applied to the glass substrate. A plurality of solar cells is laid on the first adhesive layer with the front surface of the solar cells in contact with the first adhesive layer. The solar cells are electrically connected in series in solar cell arrays. Electrodes are electrically connected at the two ends of solar cell arrays. An isolating component is provided on a first and a second path between the electrodes and a junction box. Bus-bars are laid on the path from the electrodes to the junction box. The bus-bars are electrically connected to the electrodes and to the junction box. A second adhesive layer is applied and then a solar panel back sheet is applied to complete a stack. The stack is laminated under heat and vacuum.

### 2. BRIEF DESCRIPTION OF THE DRAWINGS

FIG. 1A, is a PRIOR ART schematic drawing of structure of a conventional solar panel with a solar cell array of solar cells connected in series. FIG. 1B is a bottom view, partially cut away of the drawing of FIG. 1A.

FIG. 2A, is a PRIOR ART schematic drawing of a solar panel with the junction box at the center of the solar panel. FIG. 2B is a bottom view, partially cut away of the drawing of FIG. 2A.

FIG. 3A, is a schematic drawing of a solar panel according to the present invention. FIG. 3B is a bottom view, partially cut away of the drawing of FIG. 3A.

FIG. 4 is a cross section of the solar panel of FIG. 3B taken along line A-A.

FIG. 5 is an enlarged detailed view of the structures shown in the circle “B” in FIG. 3B.

FIG. 6 is a cross section of the view of FIG. 5 taken along line C-C.

FIG. 7 is an enlarged and exploded view of showing detail of the isolating components 380/381 in FIG. 6.

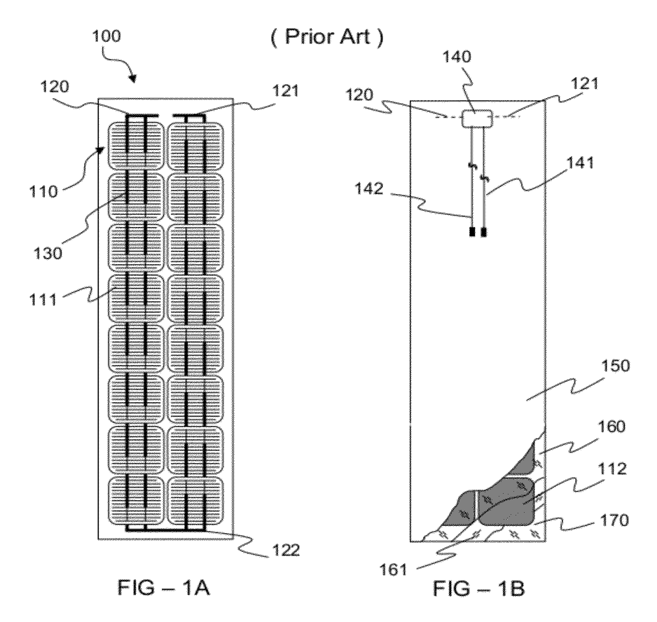

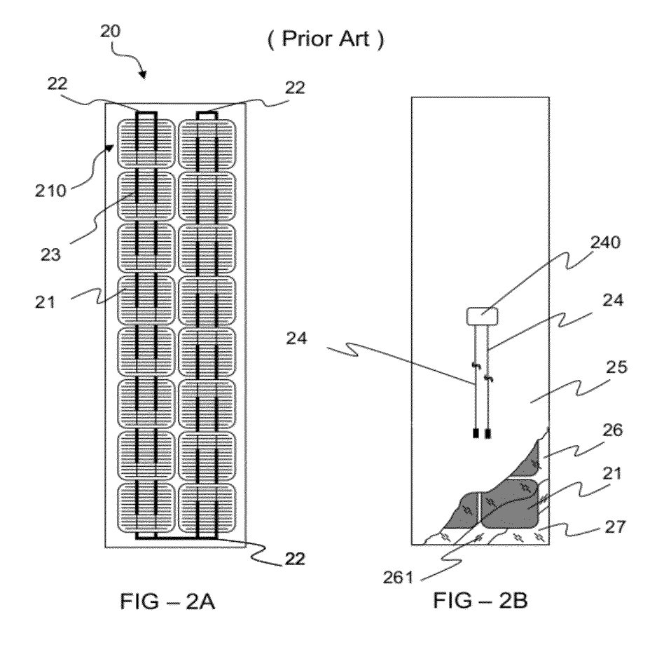

### 3. DETAILED DESCRIPTION OF THE PREFERRED EMBODIMENTS

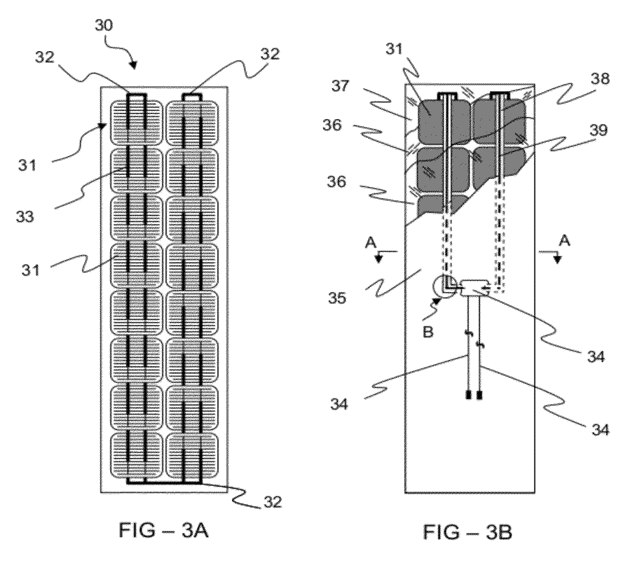

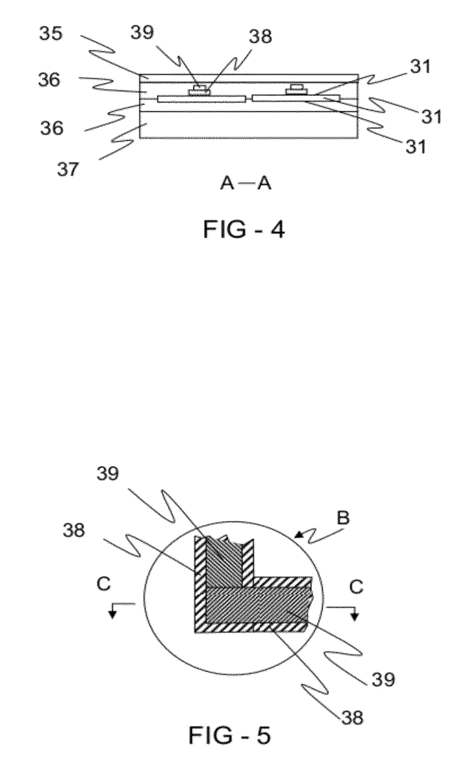

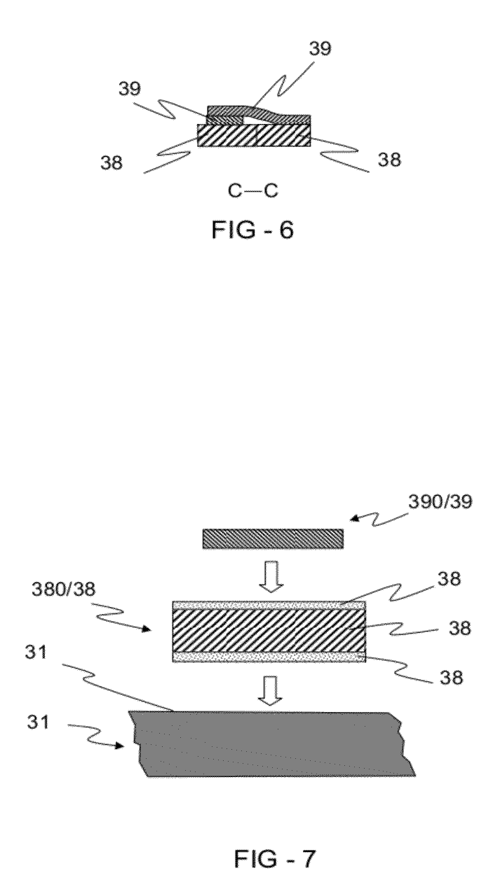

The solar panel which is generally shown at 300 in FIG. 3A and FIG. 3B is a preferred embodiment of this invention. It will be explained with reference to FIG. 3A, FIG. 3B, FIG. 4, FIG. 5, FIG. 6 and FIG. 7. The solar panel for the solar shingle is shown generally by reference numeral 300. The solar cell array 310 made from multiple solar cells. For illustration purposes, eight solar cells 311 are shown connected in series to form a strip with soldering tapes 330. Two strips are made from sixteen solar cells 311. The particular number of solar cells in each solar array is not essential to the invention, and can be varied. The front face 311 of the solar cell array 310 collects sunlight. The rear face 312 of solar cell array 310 can be seen in FIG. 3B. Soldering tape 330 is used to electrically connect the solar cells in series to form the solar cell array 310. 320 and 321 are soldering tapes for bus-bars connecting at the two ends of the solar cell array 310. A soldering tape 322 connects the two strips of solar cells in series. The back sheet 350 of solar panel 300 can be seen in FIG. 3B. A first adhesive layer 360 holds the back sheet 350 to the solar cell array 310. A second adhesive layer 361 holds the solar cell array 310 to the glass 370.

Glass 370 is a substrate of the solar panel 300, on which an adhesive layer 361 is applied. The adhesive layer 361 is an EVA (Ethylene Vinyl Acetate) film can be obtained from suppliers such as Bridgestone Corporation.

To form a solar cell array 310, the two strips of solar cells are laid in parallel on the adhesive layer 361. The front surface 311 of solar cell array 310 is faced to the adhesive layer 361. The soldering tape 322 is used to electrically connect the two strips of the solar cell array 310. The soldering tape 320 joins the electrodes at the front surface 311 of the solar cell array 310; and the soldering tape 321 joins the electrodes at the rear surface 312 of solar cell array 310.

With reference to FIG. 5 and FIG. 6, further detail of the bus-bar 390 is shown at the position where the bus-bar 390 makes a 90 degree turn before entering the junction box 340. The bus-bar 390 is soldered with another bus-bar 391 at their ends to form a 90° turning of the bars-bar leading to the junction box 340. Two isolating components are placed as shown in FIG. 5 and FIG. 6 to form its 90° angle.

FIG. 7 illustrates in greater detail the structure of the isolating components 380/381.

The preparation and the connection of bus-bars 390 and 391 will now be described. The bus-bar 391 is for turning 90° of the bus-bar 390, which is made from the same material, with the same width and same thickness as those for the bus-bar 390. A tin covered copper soldering tape (Cu:Sn=80:20) is used for the bus-bar 390 with width 4˜20 mm and thickness 0.12˜0.25 mm. The length of the bus-bar 390 is decided according the distance from the soldering tapes 320 and 321 to the junction box 340. And the length of the bus-bar 391 is to induce the bus-bar 390 into the junction box. Two of the bus-bars 390 are adopted to solder with the soldering tapes 320 and 321 as shown in FIG. 3B, respectively. The other end of the bus-bar 390 is soldered perpendicularly with an end of the bus-bar 391 as shown in FIG. 5 and FIG. 6. Therefore, two of the bus-bar 391 are positive and negative electrodes from the solar cell array 310 and will be led into the junction box 340.

The isolating components 380 and 381 are prepared in the following manner. The isolating component 381 is for turning 90° of the isolating component 380, which is with the same material, same width and same thickness as those for the isolating component 380. The substrate 384 of the isolating component 380 is made from material Polyethylene Terephthalate (PET), a high voltage insulation polyester film, or a composited stack film with PET. An example of a suitable material is PYE™ material composited by double PET layers and Ethylene Vinyl Acetate (EVA), e.g. the PYE BK 50/125/EBK 295 film which is manufactured by Coveme, Italy. There are two other composited stack films, polyvinylfluoride (Tedlar® from DuPont)+ethylene terafluoroethylene (ETFE® from Japan Asahi)+PET and polyvinylfluoride (Tedlar® from DuPont)+PET, which can be used as the substrate 384 and are called as TPT film. TPE film is another choice for the substrate 384, which is composited with polytetrafluoroethylene (PTFE® from Fluoro-Plastics®)+PET+EVA. Special adhesives are used to fix the isolating component 381 into position. Ethylene Vinyl Acetate (EVA) adhesive is preferred. On the two surfaces of the substrate 384, two EVA films 382 and 383 with thickness 0.1˜0.8 mm, e.g. LC(pp)BB-(rr)/LEV(qq)BB-(rr) film available from Bridgestone Corporation, are attached as adhesive films.

The isolating components 380 and 381 are placed between the rear surface 312 of solar cell array 310 and the bus-bars 390 and 391, respectively.

An adhesive layer 360, with the same size and material as the adhesive layer 361, is covered on the bus-bars 390, 391 and the rest area of rear surface 312 of solar cell array 310.

The back sheet 350 is placed on the adhesive layer 360.

Two bus-bars 391 are introduced out through two slots opened and aligned on the adhesive layer 360 and the back sheet 350.

The stack mentioned above is laminated using a commercial solar panel laminator under a vacuum and temperature between 100° C.˜150° C. with 10˜20 minutes in time.

A junction box 340 receives electricity generated by the solar cells and gathered by the soldering tapes 320 and 321. The electricity is conducted to the junction box by the bus-bars 390. The junction box 340 has cables 341 and 342 to carry electricity to electrically connect outside. It should be noted that the junction box 340 is positioned near the centre of the solar panel 300. The junction box 340 is glued on the outside surface of the back sheet 350. And, the bus-bars 391 are connected with cables 341 and 342 at two joints in the junction box 340.

The solar panel 300 is completed in manufacturing.

To be consistent in color appearance looking on the glass 370, the surface color of the substrate 384 facing to the adhesive film 382 is black as same as that of the back sheet 350 facing to the adhesive layer 360.

Specially, in practice, the adhesive film 383 may not be used if the width of the bus-bars 390 and 391 is less 10 mm, which will not cause a delaminating around the area of the bus-bars.

A glass sheet is adopted as the substrate. An adhesive layer 1 covers on a surface of the glass, which becomes viscose status in a high temperature above 110° C. and is colloid at room temperature, such as EVA (Ethylene Vinyl Acetate).

A solar cell array is laid on the said adhesive layer 1, which includes at least two strings of solar cells soldered one by one in series.

Two bus-bars are used to connect with and lead the two ends of the said solar cell array to a junction box which is located in the central area of the said solar cell array. The said bus-bars are laid on the back side of the said solar cell array through some rears of solar cells to reach the said junction box.

Isolating components are inserted between the said bus-bars and the said solar cell array. The said isolating components are opaque insulating sheets with length and width both larger than the said bus-bars. On both surfaces of the said isolating component, there is an adhesive layer which becomes viscose status in a high temperature above 110° C. and is colloid at room temperature, such as EVA (Ethylene Vinyl Acetate).

A second adhesive layer, adhesive layer 2, covers the said bus-bar with the same size as the said glass sheet. The said adhesive layer 2 becomes viscose status in a high temperature above 110° C. and is colloid at room temperature, such as Ethylene Vinyl Acetate.

A back sheet is covered on the said adhesive layer 2, which is composited from organic insulating material, polyethylene terephthalate, e.g. TPT (Tedlar™+polyethylene terephthalate+Tedlar™). The function of the said back sheet is to protect and isolate the said solar cell array from the outsider environment.

The stack structure mentioned above is laminated using a commercial solar panel laminator. The said junction box is glued on the said back sheet, where the said two bus-bars penetrate the said adhesive layer 2 and back sheet into the said junction box.

For the said isolating component, it can be made from an insulating sheet covered with adhesive material on the surfaces; it can also be formed by stacking the insulating sheet with adhesive films or sheets. The said insulating sheet should stand an insulation test with DC voltage of 1000 volt. As an example, TPT (DuPont™ Tedlar® polyvinyl fluoride (PVF) films+polyethylene terephthalate+DuPont™ Tedlar® polyvinyl fluoride (PVF) films) can be used as the said insulating sheet. The said adhesive material, films or sheets ensure a good bonding strength between the said isolating components and the said solar cell array, and as well as between the said isolating components and the said bus-bars, to prevent the delaminating occurring between them.

Another aspect of the invention is that the surface color of the said isolating component facing to the said solar cell array consists with that of the said back sheet facing to the said glass, so that the color difference induced by the said isolating components can be reduced or neglected.

Another aspect of the invention is related to prepare the said bus-bars. Besides the width of the said bus-bars needs to satisfy the maximum current generated by the said solar array, the turning of the said bus-bars is prepared to avoid an over-current at the turning point. To realize it, the ends of two bus-bars are connected by soldering to form a certain angle, e.g. 90°, instead of by folding a bus-bar to turn the angle.

Another aspect of the invention is that the width of the said isolating components is at least 2 mm wider than that of the said bus-bars which are located in the center of the said isolating components.

The final aspect of the invention is that the location of outlet of the said bus-bars penetrating through the said adhesive layer 2 and back sheet into the said junction box, i.e. the location of the said junction box, should be at or close to the center of length direction of the said solar panel. With this aspect of the invention, the length of cables coming out from the said junction box can be adopted comparatively shorter, so that the cost can be reduced.

By applying the aspects of the invention described above, solar panels can be manufactured specially for the said solar shingles with reliable performance, comparably low cost and easy installation.

We claim:

1. A solar plane comprising:
a) a plurality of crystalline silicon solar cells each having a front surface and a rear surface, said solar cells being electrically connected in solar arrays;
b) a bus-bar positioned adjacent the rear surfaces of the solar cells for electrical connection of the solar arrays to a junction box; and,
c) an isolating component in interposed contact between the bus-bar and the solar cells.

2. The solar panel of claim 1, wherein the bus-bar is constructed from a material selected from the group consisting of: monometallic tape, compound metallic tape, metallic tape coated with soldering metal.

3. The solar panel of claim 2, wherein the isolating component has a width which is equal to or greater than that of the bus-bar.

4. The solar panel of claim 3, wherein the isolating component is constructed from a substrate material composite of: polyethylene terephthalate, or polyethylene terephthalate and ethylene vinyl acetate, or polyvinylfluoride and polyethylene terephthalate, or polytetrafluoroethylene and polyethylene terephthalate.

5. The solar panel of claim 4, wherein the isolating component further comprises a first adhesive means on the surface of the isolating component which is in interposed contact with the solar cells.

6. The solar panel of claim 5, wherein the isolating component further comprises a second adhesive means on the surface of the isolating component which is in interposed contact with the bus-bar.

7. The solar panel of claim 6, wherein the first and second adhesive means are selected from the group consisting of: an adhesive coating applied to the isolating component, and a layer of adhesive sheeting material.

8. The solar panel of claim 7, wherein the first and second adhesive means are selected from the material composite of: ethylene vinyl acetate.

9. The solar panel of claim 8, further comprising a solar panel back sheet located to the rear of the bus-bar and a glass substrate located in front of the solar cells.

10. The solar panel of claim 9, further comprising a first adhesive layer between the solar panel backsheet and the bus-bar and a second adhesive layer between the solar cells and the glass panel.

11. The solar panel of claim 10, wherein the first and second adhesive means are selected from the material composite of: ethylene vinyl acetate.

12. The solar panel of claim 11, wherein the surface colour of the isolating component is the same as the surface colour of the back sheet.

13. In a solar plane comprising a plurality of crystalline silicon solar cells each having a front surface and a rear surface, said solar cells being electrically connected in solar arrays and a bus-bar positioned adjacent the rear surfaces of the solar cells for electrical connection of the solar arrays to a junction box, a method is provided for avoiding shorting the circuitry of solar cells and solar areas by bus-bars located between solar cells comprising the step of: providing an isolating component in interposed contact between the bus-bar and the solar cells.

14. A method of constructing a solar panel comprising the steps of:
a) providing a glass substrate;
b) applying a first adhesive layer to the glass substrate;
c) laying a plurality of solar cells with the front surface in contact with the first adhesive layer;
d) electrically connecting the solar cells at their front surfaces in solar cell arrays;
e) electrically connecting electrodes at the rear surfaces of solar cell arrays;
f) providing an isolating component on a first and a second path between the electrodes and a junction box;
g) laying bus-bars on the path from the electrodes to the junction box;
h) electrically connecting the bus-bars to the electrodes and to the junction box;
i) applying a second adhesive layer;
j) applying a solar panel back sheet to complete a stack; and,
k) laminating the stack under heat and vacuum.
